(19) United States
(12) Patent Application Publication
(10) Pub. No.: US 2023/0333294 A1
(43) Pub. Date: Oct. 19, 2023

(54) Non-Uniform-Thickness Layers and Methods for Forming

(71) Applicant: California Institute of Technology, Pasadena, CA (US)

(72) Inventors: Axel Scherer, Ph.D., Barnard, VT (US); Jack Jewell, Boulder, CO (US); Taeyoon Jeon, Pasadena, CA (US)

(21) Appl. No.: 18/134,295

(22) Filed: Apr. 13, 2023

Related U.S. Application Data
(60) Provisional application No. 63/331,033, filed on Apr. 14, 2022.

(51) Int. Cl. G02B 5/08; G02B 5/20

(52) U.S. Cl. CPC G02B 5/0816; G02B 5/208

(57) ABSTRACT

The present disclosure is directed toward the simultaneous formation of a plurality of optical elements on a common substrate, where each optical element includes at least one layer having a desired non-uniform-thickness variation. Each such layer is formed such that it includes a plurality of material patterns characterized by the non-uniform thickness variation, where each material pattern is disposed on a different deposition site on the substrate. The material patterns are configured such that adjacent optical elements are separated by a boundary region for facilitating dicing of the substrate into individual optical elements. The non-uniform-thickness layer is formed by direct deposition through a shadow mask that includes a plurality of mask patterns that are either (1) configured to pass material flux in a non-uniform manner or (2) configured to shadow different portions of their respective deposition regions while being moved relative to the substrate.

### CROSS-REFERENCE TO RELATED APPLICATIONS

This application claims the benefit of U.S. Provisional Application No. 63/331,033, filed Apr. 14, 2022 (Attorney Docket: CIT-8812-P), which is incorporated herein by reference in its entirety.

### FIELD OF THE INVENTION

The present invention relates to thin-film formation and, more particularly, to formation of thin films for optical systems.

### BACKGROUND OF THE INVENTION

There has long been a need to form thin films for mirrors, filters, anti-reflective, and other optical coatings on a wafer-scale, wherein wafers are subsequently diced into components. Often, such thin films have complex requirements, such as multiple components, thickness-gradients, step changes in thickness, and the like, which complicate their formation. For example, some conventional optical filters include a plurality of individual components, each having thickness gradients, wherein the individual components are approximately the same, or at least interchangeable, and wherein multiple components are produced in the same dimension as the gradient.

Conventional graded filters for visible and near-infrared spectroscopy have typically been produced by depositing material on a pre-diced substrate that is tilted at an angle with respect to the source of the material being deposited. The tilted orientation produces a layer that is thicker on the substrate surface closer to the source with a substantially linear reduction in thickness along the direction of the tilt. The magnitude of the gradient can be controlled by changing the distance between the source and the substrate and/or the tilt angle of the substrate, where a larger gradient can be realized by moving the substrate closer to the material source and/or increasing the tilt angle. Unfortunately, a large tilt angle can increase the difficulty of producing a high-quality layer. In addition, high-production-capacity deposition systems are large, which can limit the magnitude of the gradient.

A method for producing a high-quality gradient-thickness thin film with good reproducibility that is suitable for wafer-scale production would be a significant advance in the state of the art.

### SUMMARY

An advance is made in the art according to aspects of the present disclosure directed to methods for producing a non-uniform-thickness layer, such as a linearly graded layer, suitable for use in optical devices, such as spectral filters, optical filters, anti-reflection coatings, and other optical coatings. Furthermore, the teachings herein enable optical thin-film coatings having a controlled thickness non-uniformity that can have virtually any desired variation. Embodiments in accordance with the present disclosure are suitable for use with a wide range of deposition methods wherein a flow of deposition material is projected onto the sample from a material source, such as thermal evaporation, e-beam evaporation, sputter deposition, electron-beam deposition, plasma-enhanced chemical vapor deposition (PECVD), epitaxial deposition (e.g., atomic-layer deposition (ALD), molecular beam epitaxy (MBE), chemical vapor deposition (CVD), metal-organic chemical vapor deposition (MOCVD), etc.), and the like.

Like the prior art, the present invention employs a shadow mask containing a plurality of mask regions having at least one opening, where each mask region enables deposition material to pass through to form a material pattern on a corresponding deposition site on the surface of a substrate. Only material directed through the openings of a mask region reaches its respective deposition site.

In contrast to the prior art, the present disclosure teaches shadow masks in which each mask region either (1) includes a plurality of openings that either have a non-uniform opening-density along a first direction or (2) have a single opening that is moved along the first direction while material flux passes through it, thereby changing the amount of material flux that reaches different portions of its corresponding deposition site. By providing a shadow mask whose mask regions have a non-uniform opening-density along a first dimension and/or by moving the shadow mask along the first dimension, a controlled variation in the thickness of the deposited material patterns can be realized.

An illustrative embodiment is a shadow mask comprising a plurality of mask regions, where each mask region includes a plurality of rectangular openings arranged to form a linear array along a first direction. The width of the openings and the spacing between them changes along the linear array, thereby realizing a change in the density of the openings along the first direction.

As a flow of material is directed at the shadow mask, the different densities of the openings within each mask region control the overall material that is deposited onto a corresponding deposition site on the surface of a sample located behind the shadow mask. In other words, the density variation of the openings of a mask region controls the total amount of material flux projected through the shadow mask onto its respective deposition site to produce a corresponding thickness variation. The digital nature of the openings in each mask region are blurred out, via having an appropriate distance between the shadow mask and the target substrate. In some embodiments, the shadow mask is dithered during deposition, which can improve the blurring out of the digital nature of the openings. In some embodiments, the shadow mask is moved along the first direction during deposition to provide additional control over the resultant thickness variation at each deposition site. In some embodiments, a shadow mask includes only one mask region that is configured to produce a single deposition site that encompasses most, if not all, of the surface of the target substrate.

In some embodiments, at least one mask region is a single opening. During deposition, the shadow mask is moved along a first direction relative to the sample, which results in a difference in the amount of time that different portions of each deposition site are exposed to the flow of deposition material. By controlling the position of the mask over time, a substantially identical desired thickness variation can be achieved along the first direction at each deposition site. Desired thickness variations that can be realized include a linear gradient, multiple linear gradients (e.g., an upward ramp and a downward ramp, Vernier-like shapes, etc.), non-linear variations, and the like.

In some embodiments, a mask is moved along a first direction with non-uniform speed. In some embodiments, a mask is moved with back-and-forth motion along a first direction such that, during its motion, or at both ends of its back-and-forth motion, it is stopped in at least one fixed position for a desired time period.

An embodiment in accordance with the present disclosure is a method for forming a plurality of optical elements on a substrate, the method including forming a first layer on the substrate such that the first layer includes a plurality of material patterns on a plurality of deposition sites located on the substrate, wherein a first material pattern of the plurality of material patterns has a thickness that includes a desired non-uniformity along a first direction, and wherein the first layer is formed by operations comprising: providing a mask having a plurality of mask regions; locating the mask between a material source and the substrate; and directing a material flux from the material source through the plurality of mask regions to form the plurality of material patterns.

Another embodiment in accordance with the present disclosure is an apparatus comprising: a plurality of optical elements disposed on a substrate, each optical element including a different portion of a first layer that includes a plurality of material patterns, wherein each material pattern has a thickness that has a desired non-uniformity along a first direction; and a plurality of boundary regions, each boundary region being located between a pair of adjacent material patterns along the first direction.

### BRIEF DESCRIPTION OF THE DRAWINGS

FIG. 1 depicts a schematic drawing of a cross-sectional view of an optical element having a non-uniform thickness layer in accordance with the present disclosure.

FIG. 2 depicts operations of a method for forming an optical element in accordance with the present disclosure.

FIG. 3 depicts sub-operations suitable for use in operation 202 to form an optical layer having a controlled non-uniform thickness along one dimension.

FIG. 4 depicts a cross-sectional view of a deposition system in accordance with the present disclosure.

FIG. 5 depicts a schematic drawing of a plan view of a portion of a first exemplary mask in accordance with the present disclosure.

FIG. 6 depicts the parametric relationship/guidelines for mask 408 for the configuration of system 400.

FIG. 7 depicts a schematic drawing of a cross-sectional view of a portion of nascent element 100′ after the formation of spacer layer 106.

FIG. 8 depicts a plot of simulated transmission through optical element 100.

FIG. 9 depicts a series of plots of measured transmission spectra of element 100 at different points along the x-direction.

FIG. 10 depicts a schematic drawing of a plan view of a portion of a second exemplary shadow mask in accordance with the present disclosure.

FIG. 11 depicts sub-operations suitable for use in an alternative operation 202 of method 200 for forming an optical layer having a controlled non-uniform thickness along one dimension.

FIG. 12A depicts a schematic drawing of a plan view of a portion of mask 1000 at two points of its motion during sub-operation 1103 of alternative operation 202A.

FIG. 12B depicts a schematic drawing of a cross-sectional view of spacer layer 1202, as formed during alternative operation 202A using mask 1000.

FIG. 13 depicts a schematic drawing of a plan view of a portion of a second alternative shadow mask in accordance with the present disclosure.

FIG. 14A depicts a schematic drawing of a plan view of a portion of mask 1300 at two points of its motion during sub-operation 1103 of alternative operation 202A.

FIG. 14B depicts a schematic drawing of a cross-sectional view of a non-uniform-thickness layer formed during alternative operation 202A using mask 1300.

FIG. 14C depicts a schematic drawing of a cross-sectional view of a non-uniform-thickness layer formed during alternative operation 202A using mask 1300, including mask stopping at each extreme position of its motion.

FIG. 15 depicts a schematic drawing of a plan view of a portion of a third alternative shadow mask in accordance with the present disclosure.

FIG. 16A depicts a schematic drawing of a plan view of a portion of mask 1500 at two points of its motion during sub-operation 1103 of alternative operation 202A.

FIG. 16B depicts schematic drawings of cross-sectional views of two different non-uniform-thickness layers formed during alternative operation 202A using mask 1500, with and without including mask stopping, respectively.

FIG. 17 depicts plan views of two substrates on which a non-uniform-thickness layer has been formed in accordance with the present disclosure.

FIG. 18 depicts schematic drawings of cross-sectional views of some alternative optical elements in accordance with the present disclosure.

### DETAILED DESCRIPTION

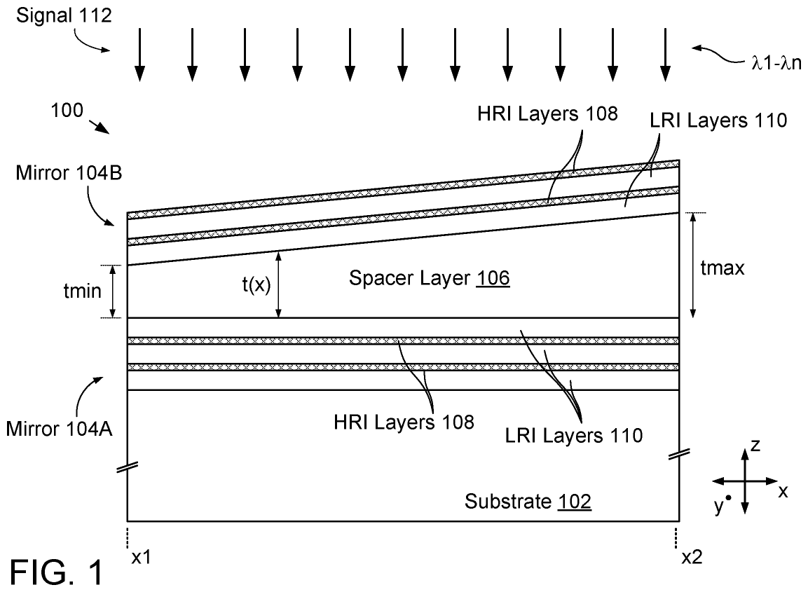

FIG. 1 depicts a schematic drawing of a cross-sectional view of an optical element having a non-uniform thickness layer in accordance with the present disclosure. Optical element 100 includes substrate 102, Mirrors 104A and 104B, and spacer layer 106. Element 100 is a spectral filter configured for operation in the mid-infrared (MIR) spectral range.

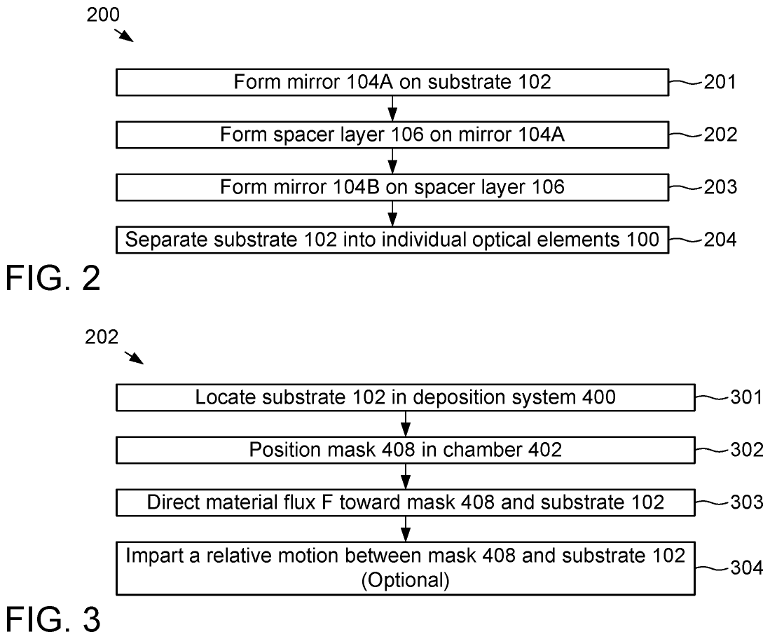

FIG. 2 depicts operations of a method for forming an optical element in accordance with the present disclosure. Method 200 begins with operation 201, wherein mirror 104A is formed on substrate 102. Method 200 is described with continuing reference to FIG. 1, as well as reference to FIGS. 2-6.

Substrate 102 is a conventional substrate suitable for use in a planar-processing fabrication method. In the depicted example, substrate 102 comprises silicon; however, any suitable material can be used for substrate 102 without departing from the scope of the present disclosure.

Mirror 104A is a multi-layer Bragg mirror comprising a stack of alternating uniform-thickness high-refractive-index (HRI) layers 108 and low-refractive-index (LRI) layers 110. Each of HRI layers 108 comprises material M1, which is a material having relatively higher refractive index, and each of LRI layers 110 comprises material M2, which is a material having relatively lower refractive index. In the depicted example, each of the HRI and LRI layers in mirror 104A has a thickness equal to ¼ of the center wavelength λc (within its respective material) of the operating spectrum of element 100.

HRI layers 108 and LRI layers 110 are formed on substrate 102 via a conventional deposition method. Deposition methods suitable for use in accordance with the present disclosure include, without limitation, thermal evaporation, e-beam evaporation, sputter deposition, electron-beam deposition, PECVD, epitaxial deposition (e.g., ALD, MBE, CVD, MOCVD, etc.), and the like.

In the depicted example, M1 is germanium having a refractive index of 4.0 and M2 is a fluoride having a refractive index of 1.5, and mirror 104A includes 2½ pairs of HRI and LRI layers.

At operation 202, a controlled non-uniform-thickness layer is formed. In the depicted example, the non-uniform-thickness layer is spacer layer 106, which is formed on mirror 108A.

Spacer layer 106 is a layer of HRI material disposed between mirrors 104A and 104B. Spacer layer 106 has a thickness t(x) that is non-uniform along one dimension. In the depicted example, the thickness of the spacer layer increases linearly along the x-direction (as shown) from tmin at x1 to tmax at x2, where tmin=800 nm and tmax=1200 nm.

FIG. 3 depicts sub-operations suitable for use in operation 202 to form an optical layer having a controlled non-uniform thickness along one dimension. In the depicted example, operation 202 begins with sub-operation 301, wherein substrate 102 is located in deposition system 400.

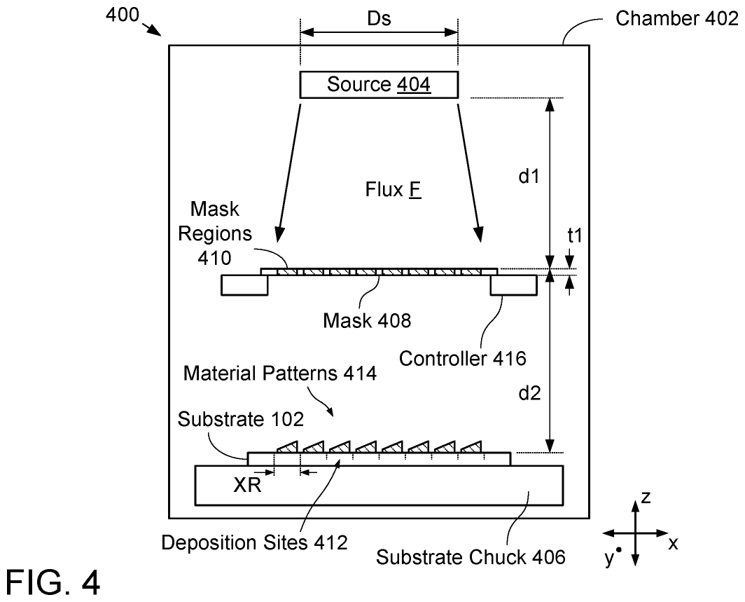

FIG. 4 depicts a cross-sectional view of a deposition system in accordance with the present disclosure. System 400 includes chamber 402, which encloses material source 404, substrate chuck 406, and mask 408.

Chamber 402 is a conventional low-pressure chamber suitable for use in thin-film deposition. Although not shown, chamber 402 is operatively coupled with a vacuum system that enables a suitable low-pressure environment within the chamber.

Material source 404 (hereinafter referred to as “source 404”) is a conventional material source configured to generate flux, F, of material toward substrate 102. As noted above, a wide range of material sources (e.g., evaporative sources, sputter-deposition targets, etc.) can be used in source 404 without departing from the scope of the present disclosure. In the depicted example, source 404 is an evaporation source for generating a plume of vaporized material M1 to provide flux F.

Substrate chuck 406 is a conventional platen for holding substrate 102 in a desired physical relationship with source 404.

Mask 408 is a shadow mask comprising a plurality of mask regions 410, each of which corresponds to a different deposition site 412 on substrate 102, where each deposition site has width XR along the x-direction and height YR along the y-direction. In the depicted example, mask 408 is a “gray-scale” shadow mask that is configured to give rise to a substantially identical material patterns 414 in each deposition site 412, where each material pattern has a linear gradient along the x-direction.

In the depicted example, mask 408 is held in mask controller 416, which is operative for imparting motion on the mask in at least the x-direction.

At sub-operation 302, mask 408 is positioned in chamber 402 such that the mask is aligned with substrate 102 and separated from source 404 by distance d1 and from substrate 102 by distance d2.

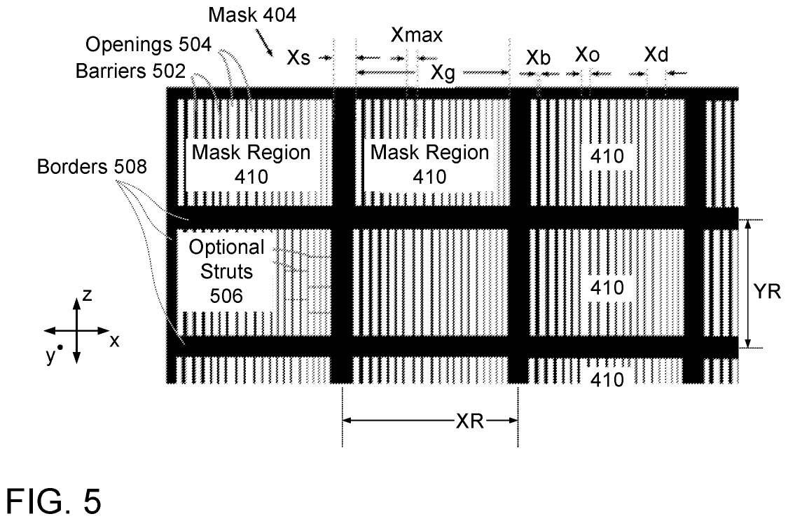

FIG. 5 depicts a schematic drawing of a plan view of a portion of a first exemplary mask in accordance with the present disclosure.

Each mask region 410 includes a series of bar-shaped barriers 502 and openings 504 having barrier width X_{b} and opening width Xₒ, respectively. Along the x-direction, the value of X_{b} decreases, while the value of Xₒ increases. In other words, the magnitude of each barrier width and opening width is based upon its position within the series.

It should be noted that, although the depicted example includes barriers 502 and openings 504 that are bar shaped, the barriers and openings of a mask in accordance with the present disclosure can have any practical shape (e.g., small openings whose density varies analogously to “gray-scale” production of newspaper images, etc.).

It should be noted that mask 408 includes optional struts 506, which are included to enhance the structural stability of the mask. In the depicted example, struts 506 are laterally oriented bars; however, a myriad of strut shapes, in any desired orientation, can be used without departing from the scope of the present disclosure.

Each mask region 410 is surrounded by borders 508 in both in the x- and y-dimensions. In addition to separating the mask regions, borders 508 are relatively wide such that they are configured to add strength and stability to mask 408.

At sub-operation 303, source 404 directs material flux F toward mask 408 and substrate 102.

As material flux F passes through mask 408, the portions of deposition site 412 lying directly below the portions of mask region 410 having the widest openings and narrowest barriers will receive a material flux only slightly less than F, whereas the portions below mask regions having wide barriers and thinner openings will receive a material flux much less than F. Since all portions of substrate 102 are exposed for about the same time, the lower-flux portions will have thinner layers than the higher-flux portions. In other words, as flux F passes through mask region 410, the wider openings allow more material to pass such that material pattern 414 will be thickest where the barrier widths are smallest and the opening widths largest.

When borders 508 are very wide, the portions of substrate 102 located below them will receive little or no flux F, thereby forming a material layer having a thickness that is significantly less than the minimum thickness of material pattern 414 and, in some cases, is substantially equal to zero.

It should be noted that, for explanatory purposes, an average flux F is assumed; however, flux F can be different for different materials. Furthermore, in some embodiments, flux F varies over time.

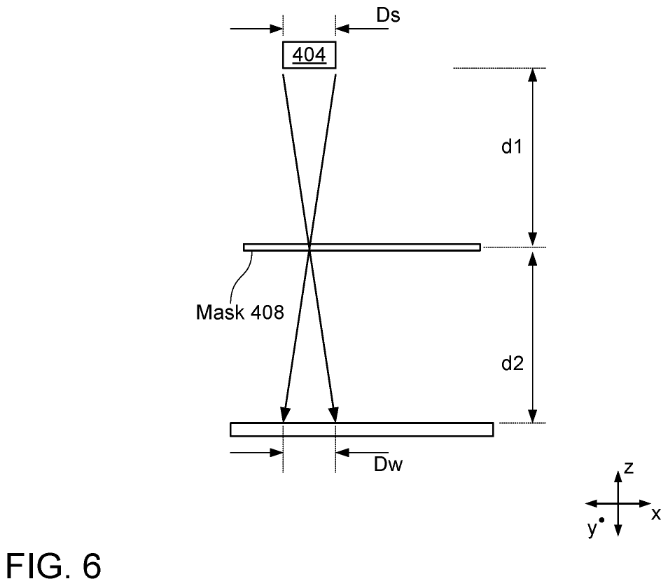

FIG. 6 depicts the parametric relationship/guidelines for mask 408 for the configuration of system 400. The parametric relationship for a mask in accordance with the present disclosure is described with continuing reference to FIGS. 4-6.

As will be apparent to one skilled in the art, after reading this Specification, for source 404 having an infinitely small diameter located very close to substrate 102, material flux passing through a single point of the mask will strike a single point on the substrate, and the mask pattern will be reproduced on the substrate with substantially perfect fidelity.

However, for system 400, using a source 404 having a practical diameter Ds, material passing through a single point on the mask will have a diameter of Dw, which is approximately equal to [Dₛ×d₂÷d₁].

Additionally, the sizes of material patterns 414 on substrate 102 will be magnified by the sizes of mask regions 410 by a factor equal to (d₁+d₂)/d₁. When d₁>>d₂, this magnification is approximately 1.0.

It is an aspect of the present disclosure that, to deposit a smoothly-varying-thickness of material on the substrate rather than reproducing an image of mask 408 on the substrate, Dw must be significantly larger than the maximum feature size on the mask, Xmax, whether it be a barrier or an opening. We express the relationship of the sizes in terms of an arbitrary constant k, (i.e. Dw=k(Xmax)), wherein k may be considered a criterion for smoothly-varying material thickness. Thus Dw=k(Xmax)=Ds(d₂/d₁). A system may be designed via the inequality: [d₂≥d₁×k×Xₘₐₓ÷Dₛ].

The separation distance between mask 408 and substrate 102 (i.e., distance d2) is typically the most freely controlled system parameter. For example, using a criterion of k=3 means that d₂≥d₁×3×xmax÷Ds. It is usually desirable for Xmax to be as small as possible, with Xmax=0.1 mm being a reasonable technological minimum in practice. For a source diameter Ds=3 mm, the design yields d₂≥d₁×3×0.1÷3. A d₁=300 mm yields d₂>30 mm. For a criterion k=2 (a 0.1 mm feature will be spread over 0.2 mm), and the other exemplary values, such an exemplary design yields d₂>20 mm.

It should be noted that the analysis provided above applies to system 400 having a fixed-position mask 408 configured to give rise to a one-dimensional gradient in a deposited material pattern 414. Such a “static” mask approach simplifies construction and operation in practice, where production-quality deposition tools are configured as “planetary motion” systems in which a plurality of substrates are rotated around one or more fixed-position sources while the substrates, themselves, are rotated about their center point during deposition.

At optional sub-operation 304, a relative motion between mask 408 and substrate 102 is induced. In the depicted example, this motion is induced by controller 416, which “dithers” mask 408 along the x-direction. The inclusion of sub-operation 303 is particularly attractive when the desired value of d2 is unacceptably large. In some embodiments, a different relative motion (e.g., linear translation of one or both of the mask and substrate, etc.) between mask 408 and substrate 102 is induced.

The inclusion of dithering motion over a distance of m*Xmax during deposition of material patterns 414 can reduce the value of k, in the above analysis, by approximately the value of m. For example, using a nominal value of k of 3.25 and a dither of 1.75*Xmax, the effective value of k can be reduced to 1.5.

Dithering mask 408 is particularly attractive in large material deposition systems, such as those in which d₁ is much larger than 200 mm. It is preferable, but not necessary, to dither close to an integral number of half-periods (where a full period is the complete back-and-forth movement of the mask) for the deposition of the layer. While even a single half-period of motion is sufficient to yield a full thickness gradient in the deposited material, multiple-half-period motion is preferred.

It is also preferable that the thickness of mask 408 is less than or equal to the smallest of the opening widths Xₒ. For example, if the smallest opening width is 0.1 mm, it is preferred for the stencil mask to have a thickness that is approximately 0.1 mm or less.

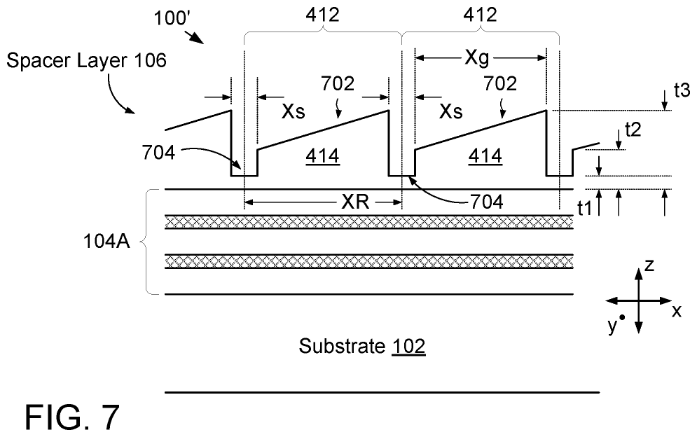

FIG. 7 depicts a schematic drawing of a cross-sectional view of a portion of nascent element 100′ after the formation of spacer layer 106.

Spacer layer 106 has a thickness that varies from a minimum t1 to a maximum t3 across the plurality of deposition sites 412. In the depicted example, the thickness variation across a deposition site is approximately linear along the x-direction; however, the layer thickness can have virtually any profile.

Each deposition site 412 includes gradient region 702 and optional boundary region 704. Boundary regions 704 provide regions in which dicing can be performed to singulate individual devices from substrate 102 while mitigating damage to the remaining portions of element 100. Within gradient region 702, the layer thickness changes linearly from t2 to t3 across its width Xg.

In boundary region 704, the thickness of spacer layer 106 is substantially uniform with thickness t1 over width Xs. It should be noted that thickness t1 can have substantially any value less than or equal to the maximum thickness of spacer layer 106, such as zero, less than t2 (as shown), approximately equal to t2, approximately equal to t3, etc. In some embodiments, it is preferred that t1 is approximately zero.

As a result, the total width of each deposition site 412 is XR=Xg+Xs. The inclusion of boundary regions 704 facilitate singulation of multiple optical elements from substrate 102.

Returning now to method 200, at operation 203, mirror 104B is formed on the top surface of spacer layer 106.

Mirror 104B is a multi-layer Bragg mirror comprising a stack of alternating uniform-thickness HRI layers 108 and LRI layers 110. Mirror 104B is analogous to mirror 104A. In the depicted example, mirror 104B includes two pairs of quarter-wavelength-thick HRI and LRI layers.

It will be clear to one skilled in the art, after reading this Specification, that any number of HRI and LRI layers can be used in one or both of mirrors 104A and 104B without departing from the scope of the present disclosure. Typically, the number of HRI and LRI layers in a Bragg mirror is larger than depicted herein (particularly for narrow-band optical elements, such as spectral filters); however, some optical elements in accordance with the present disclosure include one or more layer-based structures (e.g., anti-reflection structures, and the like) that include as few as a single non-uniform-thickness layer.

Furthermore, although the depicted example includes only one layer having a non-uniform thickness, in some embodiments, more than one layer of an optical element has a non-uniform thickness. Still further, the teachings of the present disclosure enable thickness non-uniformities other than linear gradients. For example, for a variety of reasons, it can be desirable that a non-uniform thickness layer in accordance with the present disclosure be nonlinear with respect to wavelength. With a linear thickness variation, the transmission-peak wavelength will be approximately linear with distance in response to an approximately-linear thickness variation, but slightly nonlinear due to variations in refractive indices with wavelength. In some embodiments, therefore, small modifications to the linearity of the thickness of a layer are included such that the layer produces a more-linear wavelength dependence with distance along the gradient of the thickness variation. In some embodiments, substantial modifications to the thickness gradient are included to produce a response in which the wavenumber variation is more linear with respect to the thickness gradient. Linear wavenumber variation is attractive to many spectroscopists. Desired nonlinearities in thickness may be produced by appropriate design of mask 408 and/or by appropriate programming of its motion along the x-direction (or other direction(s) as desired).

In some embodiments, element 100 is configured as a dielectric narrow-bandpass Fabry-Perot filter, where all of its constituent layers are graded uniformly. In such embodiments, the transmission wavelength at any point along the x-direction will be approximately proportional to the thicknesses of the layers at that point.

It should be noted that the materials included in any of the embodiments disclosed herein are merely exemplary and that a wide range of suitable substrate, graded-layer, HRI, and LRI materials can be used without departing from the scope of the present disclosure.

Although, in the depicted example, each of the HRI and LRI layers in mirrors 104A and 104B has a thickness that is equal to λc/4n, wherein n is the refractive index of the respective layer, in some embodiments, the thickness of at least one the constituent HRI and LRI layers in at least one of mirrors 104A and 104B is equal to a different odd-integer multiple of λc/4n (e.g., 3λc/4n, 5λc/4n, etc.). Furthermore, in some embodiments, a wavelength other than λc within the spectral range of light signal 112 is used as the reference wavelength upon which mirror-layer thicknesses are based. It is also possible for mask 404 to comprise mask regions 410 in which at least a second mask region 410 differs from a first mask region 410, in the extreme having each mask region 410 with a unique pattern.

At operation 204, substrate 102 is diced into individual die, each containing a different optical element. In the depicted example, once diced apart, every optical element is a substantially identical copy of optical element 100. In some embodiments, however, a different optical element is formed on at least one deposition site of substrate 102.

It should be noted that, after dicing, each resultant die will include a substantially annular region in which the thickness of the layers disposed on substrate 102 is less than the thickness of the layers within gradient region 702. In some embodiments, such as some of those discussed below, only a portion of this annular region has a thickness that is less than that of the layers within a gradient region enclosed therein.

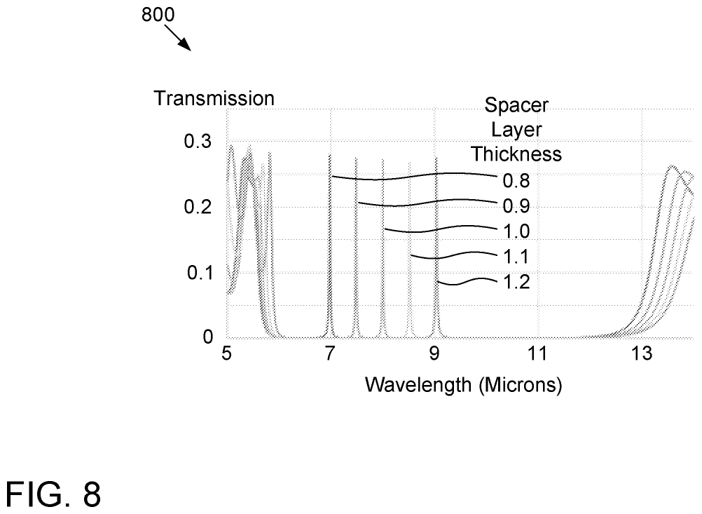

FIG. 8 depicts a plot of simulated transmission through optical element 100. Plot 800 indicates a desired thickness for spacer layer 106 that ranges from about 0.8 micron to 1.2 micron to produce a filter having peaks in the 7-9 um range.

FIG. 9 depicts a series of plots of measured transmission spectra of element 100 at different points along the x-direction. This optical element 100 was produced by a sliding shadow mask, to be described.

The spectra were taken with a Fourier-transform infrared (FTIR) spectrometer. Transmission peaks are seen at wavelengths of 11.4, 10.0, 9.1, 8.2, 6.9, and 6.1 um, with longer-wavelength transmission corresponding to points along the x-direction at which spacer layer 106 has larger thickness. It should be noted that the large beam size in the FTIR, combined with the steep gradient in the filter, cause the measured peaks to be broader than the intrinsic capability of the filter. The peaks at the extreme ends of the data are further broadened due to the mirrors having lower reflectivity far from their design wavelength of about 8 microns.

Although the embodiments described thus far employ a “stencil” shadow mask in which each mask region includes a plurality of openings, in some embodiments, a “sliding” shadow mask is employed to generate a non-uniform-thickness layer. A sliding shadow mask comprises a plurality of mask regions, each of which includes a single large-area opening. Adjacent mask regions are separated by large-area barriers. As discussed below in more detail, in order to produce a non-uniform-thickness material pattern, such as spacer layer 106, the sliding shadow mask is moved laterally, in at least one direction, during deposition of material, thereby changing the amount of time certain regions are exposed to flux F.

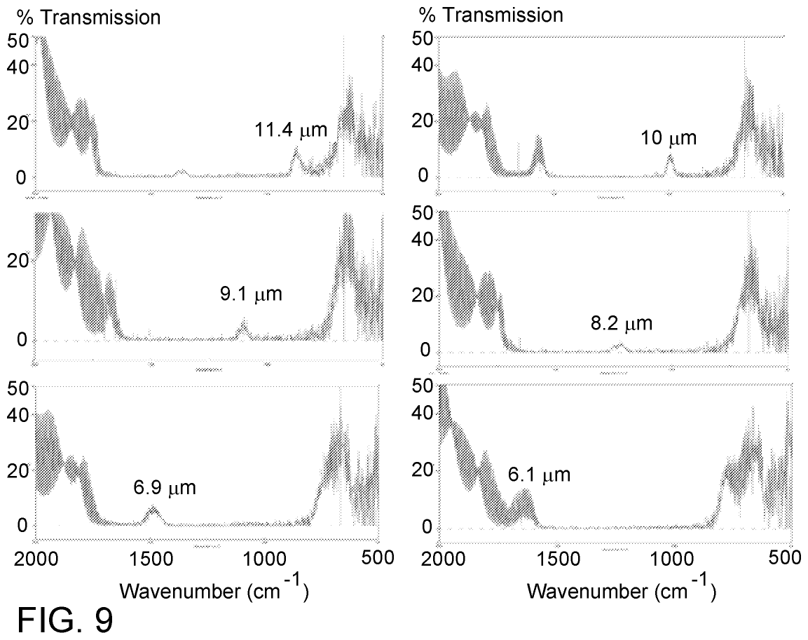

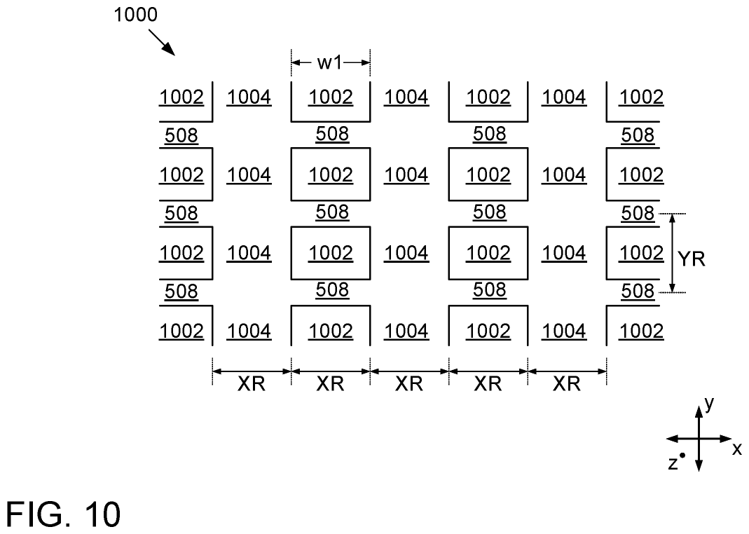

FIG. 10 depicts a schematic drawing of a plan view of a portion of a second exemplary shadow mask in accordance with the present disclosure. Mask 1000 includes a plurality of mask regions 1002, which are separated along the x-direction by barriers 1004 and along the y-direction by borders 508. Mask regions 1002 are analogous to mask regions 410 described above; however, each mask region 1002 corresponds to two adjacent deposition sites 412 on substrate 102 (as discussed above).

Each mask region 1002 is a rectangular opening having width, w1, equal to the width, XR, of its respective deposition site 412 along the x-direction and a height along the y-direction that is slightly less than that the height, YR, of its respective deposition site. Mask regions 1002 are spaced apart along the x-direction by a barrier 1004 having width XR.

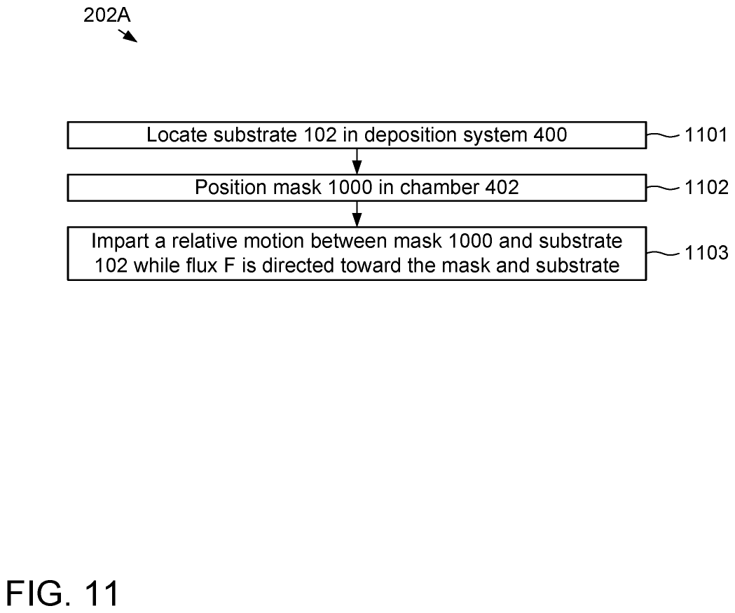

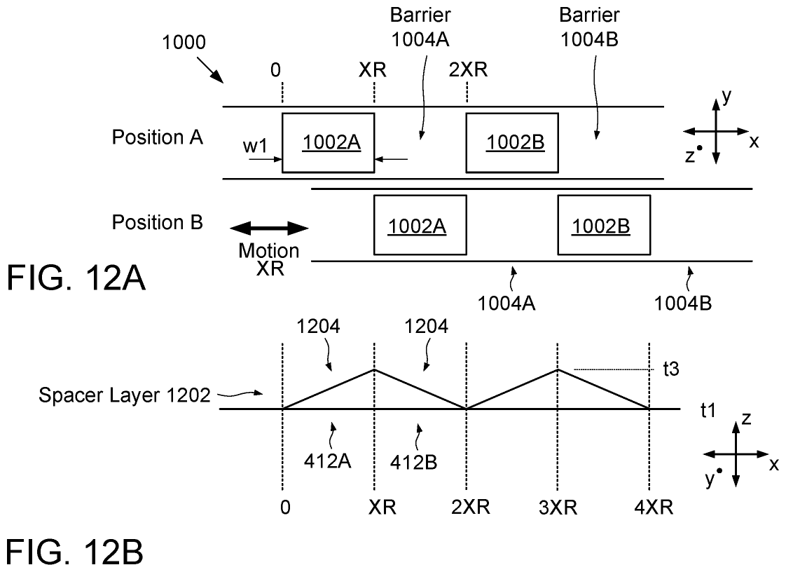

FIG. 11 depicts sub-operations suitable for use in an alternative operation 202 of method 200 for forming an optical layer having a controlled non-uniform thickness along one dimension. Alternative operation 202A begins with sub-operation 1101, wherein substrate 102 is located in deposition system 400. Alternative operation 202A is described herein with continuing reference to FIG. 4, as well as reference to FIGS. 12A-B.

At sub-operation 1102, mask 1000 is positioned in chamber 402 such that the mask is aligned with substrate 102 and separated from source 404 by distance d1 and from substrate 102 by distance d2.

At sub-operation 1103, a relative motion between mask 1000 and substrate 102 is induced by controller 416. In the depicted example, the relative motion is a lateral movement along the x-direction in which mask 1000 is moved at a substantially constant velocity in the positive x-direction by distance XR and then moved back to its original position at the same constant velocity. In some embodiments, one or both of mask 1000 and substrate 102 is moved at other than a constant velocity.

FIG. 12A depicts a schematic drawing of a plan view of a portion of mask 1000 at two points of its motion during sub-operation 1103 of alternative operation 202A. In FIG. 12A, mask 1202 is shown at the two extreme positions of its motion along the x-direction during operation 202A.

FIG. 12B depicts a schematic drawing of a cross-sectional view of spacer layer 1202, as formed during alternative operation 202A using mask 1000. Spacer layer 1202 is analogous to spacer layer 106 described above.

When mask 1202 is moved at constant speed back and forth during operation 202A, the resulting thickness of spacer layer 102 has approximately a sawtooth-shaped shape with linear gradient regions 1204, wherein adjacent deposition sites (e.g., 412A and 412B) have thickness gradients in opposite directions.

At x=XR (i.e., where opening 1002A and barrier 1004A meet), substrate 102 is constantly exposed to the flux F; therefore, spacer layer 1202 has its maximum thickness, t3, at this point. At x=2XR (i.e., where opening 1002B and barrier 1004A meet), substrate 102 receives substantially zero flux; therefore, spacer layer 1202 has substantially zero thickness.

Unfortunately, because openings 1002 of mask 1000 have the same width as deposition regions 412, graded layer 1202 includes boundary regions formed wherein gradient regions 1204 meet at every other integer value of XR (e.g., at x=XR, 3XR, . . . ) have the maximum thickness of t3, while at the rest of the boundary regions (e.g., at x=2XR, 4XR, . . . ) graded layer 1202 includes boundary regions having minimum thickness t1. Due to damage that occurs at these boundary regions during substrate dicing, the utility of these boundary regions is degraded.

It is an aspect of the present disclosure, however, that by employing a mask having mask regions wider than their respective deposition sites along the direction of motion of the mask during operation 202A this disadvantage can be mitigated.

FIG. 13 depicts a schematic drawing of a plan view of a portion of a second alternative shadow mask in accordance with the present disclosure. Mask 1300 is analogous to mask 1000 and includes a plurality of mask regions 1302, which are separated along the x-direction by barriers 1304 and along the y-direction by borders 508. Mask regions 1302 are analogous to mask regions 410 described above; however, each mask region 1302 corresponds to two adjacent deposition sites 412 on substrate 102.

Mask regions 1302 are also analogous to mask regions 1002 described above; however, each mask region 1302 is a rectangular opening having width, w2, that is larger than XR by factor f, i.e. (1+f)*XR and the width of barriers 1304 between mask regions 1302 is (1−f)*XR. As a result, each mask region 1302 has a width XR+Xe along the x-direction. In other words, each mask region 1302 is slightly wider along the x-direction than its respective deposition site 412. Mask regions 1302 are spaced apart along the x-direction by a distance equal to 2*XR.

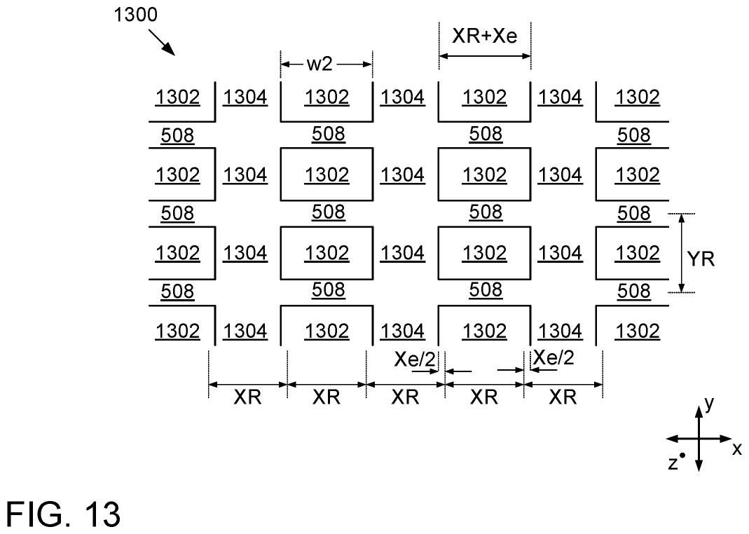

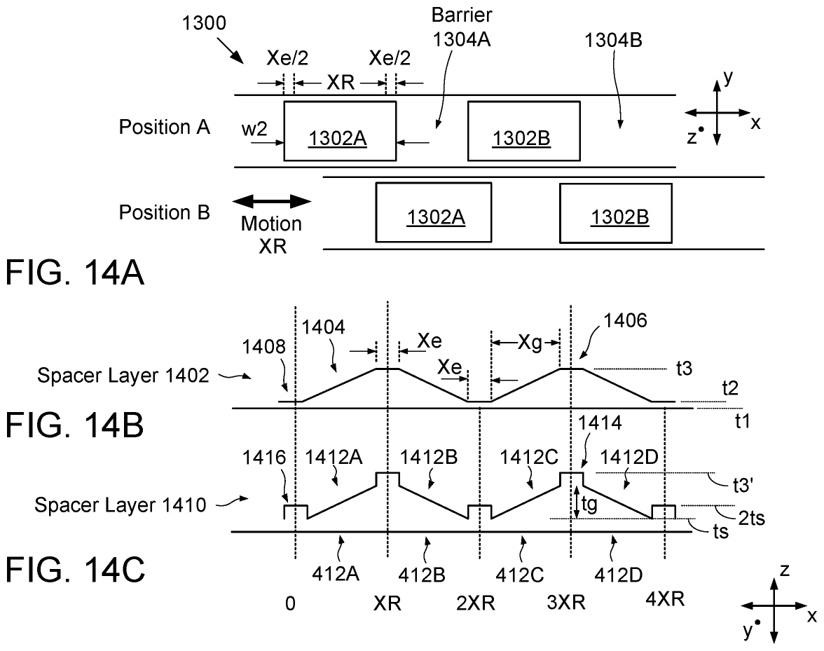

FIG. 14A depicts a schematic drawing of a plan view of a portion of mask 1300 at two points of its motion during sub-operation 1103 of alternative operation 202A.

FIG. 14B depicts a schematic drawing of a cross-sectional view of a non-uniform-thickness layer formed during alternative operation 202A using mask 1300. Spacer layer 1402 is analogous to spacer layer 106 described above.

The use of mask 1300 during sub-operation 1103 of alternative operation 203B give rise to spacer layer 1402 having gradient regions 1404, each of which has width Xg=(1−|f|)*XR, where |f| is the absolute value of f.

It also produces boundary regions 1406 and 1408, which are analogous to boundary regions 704 having width XS, as described above.

Boundary regions 1406 have the same maximum thickness as spacer layer 1202; however, their width, Xe, is formed by a constant exposure to the flux, where Xe=f*XR. It should be noted that Xe is analogous to Xs, the width of boundary regions 704, described above and with respect to FIG. 7. Boundary regions 1406 are formed at every other boundary between deposition sites 412 (e.g., between deposition sites 412A and 412B and between deposition sites 412C and 412D, etc.).

At the boundaries between the other deposition sites (e.g., between deposition sites 412B and 412C and between deposition sites 412D and 412E, etc.), however, substrate 102 receives very little material flux (typically slightly greater than zero), giving rise to boundary regions 1408, which also have width Xe but have a thickness equal to t2=f*t3.

For f>0 (or |f|>0), a preferable value of f is based upon anticipated width of damage due to dicing. In some embodiments, a practical thickness range is t2/t3˜f.

As discussed above, after dicing, each resultant die will include a substantially annular region that includes portions of each of boundary regions 1406 and 1408, as well as the boundary region located beneath borders 508 during deposition of graded layer 1402. As a result, the portions of this annular region including boundary regions 1406 and the regions beneath borders 508 have a thickness that is less than that of gradient region 1404.

In some embodiments, the motion of mask 1300 (or other masks in accordance with the present disclosure) is not a back-and-forth movement at constant velocity but, instead, includes mask stopping, wherein the motion of the mask includes one or more stopping times, during which the mask is held at a fixed position. In some such embodiments, stopping periods are included while the mask is at the extreme left and right positions of its travel to, for example, reduce wavelength variation in the resultant layer (e.g., spacer layer 1402).

FIG. 14C depicts a schematic drawing of a cross-sectional view of a non-uniform-thickness layer formed during alternative operation 202A using mask 1300, including mask stopping at each extreme position of its motion. Spacer layer 1410 is analogous to spacer layer 106 described above.

Stopping mask 1300 at both of its the extreme positions during operation 202A adds static thickness, ts, which is a constant-thickness(portion across the entire width, Xg, of each of gradient regions 1412A-D. The maximum thickness of gradient regions 1412A-D, therefore, is ts+tg.

Also, during both stopping periods, material flux, F, builds up in boundary regions 1414 and 1416, such that the material in these regions has a thickness equal to twice static thickness, ts (i.e., 2*ts). In other words, while mask 1300 in its leftmost position, material of thickness ts is deposited uniformly in gradient region 1412A, and in half the boundary regions 1414 and 1416 located on either side of it, while no material is deposited in gradient region 1412B. In similar fashion, while mask 1300 in its rightmost position, material is deposited uniformly on gradient region 1412B, and in half the boundary regions 1414 and 1416 located on either side of it, while no material is deposited in on gradient region 1404A.

As discussed herein, stopping time Tₛ is defined as the time during which a mask is stationary at each end of its travel during operation 202A, T_{M} is defined as the total moving time (i.e., the time spent moving in both directions) for the mask during operation 202A, and fractional stopping time, T_{F} is defined as the ratio of the stopped time Tₛ to the sum of Tₛ and the moving time T_{M} of the mask during operation 202A (i.e. T_{F}=Tₛ/(Tₛ+T_{M})). As a result, the total time to produce such a non-uniform-thickness layer is (T_{M}+2*Tₛ), since the stopping time must be employed twice (assuming a desire that the regions on substrate 102 are identical).

In the above example, with f=0.25 and mask 1300 held in each of its leftmost and rightmost positions, using a fractional stopping time (T_{F}=0.5), the thickness variation of graded layer 1402 is reduced by 50%.

Furthermore, for a given sliding mask and a given f, the range of thickness variation in a deposited layer can be tailored, for example, to match the desired wavelength range of an optical device. With both fractional width and stop time employed, the ratio of minimum thickness to maximum thickness is given by tₘᵢₙ/tₘₐₓ=t2/t3=[1−(1−f)*(1−T_{F})].

As a result, a formula suitable for designing a graded-thickness layer can be defined as: T_{F}={1−[(1−tmin/tmax)/(1−f)]}. [1].

As depicted in FIG. 8, element 100 having graded layer 106, with a thickness variation from 0.8 micron to 1.2-micron yields transmission peaks in the spectral range from 7-9 microns. While the performance shown in FIG. 8 is realized using method 200, a device having substantially the same performance can be produced using mask 1300 in operation 202A, with f=0.667. However, having f=0.667 means that the boundary regions 1414 and 1416 would occupy 0.667 of the component width XR and the graded regions 1412A-D would occupy only 0.333 of the component width XR. The linear efficiency is equal to (1−|f|).

By including mask stopping, however, higher linear efficiency can be obtained using a smaller f. For example, using mask 1300 having f=0.10, employing mask stopping with a T_{F}=0.63 results in a linear efficiency of 0.9, approximately 2.7 times higher than without the use of sliding mask stopping. This increase in linear efficiency enables a greater number of optical elements to be produced on a given substrate.

Unfortunately, employing mask stopping with a sliding mask having f>1.0 can be problematic because regions 1414 and 1416 receive material deposition during both stopping positions. As a result, they receive twice the static thickness ts of material in addition to the thicknesses deposited in producing the gradient regions 1412. This results in the height of regions 1414 being higher than the highest point of the gradients with a thickness equal to (t3′+ts). Such extremely thick regions 1414 can cause significant issues during the dicing operations used to singulate substrate 102 into separate chips. It is another aspect of the present disclosure that the use of a “sliding” mask having openings that are narrower than its barriers along the direction of motion (e.g., the x-direction) during alternative operation 202A can mitigate this issue.

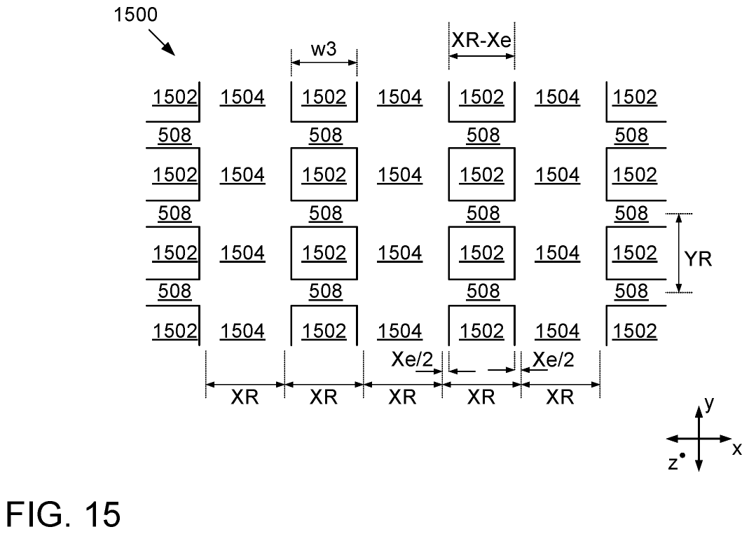

FIG. 15 depicts a schematic drawing of a plan view of a portion of a third alternative shadow mask in accordance with the present disclosure. Mask 1500 is analogous to mask 1300 and includes a plurality of mask regions 1502, which are separated along the x-direction by barriers 1504 and along the y-direction by borders 508. Mask regions 1502 are analogous to mask regions 1302 as described above; however, each mask region 1502 is a rectangular opening having a width, w3, that is less than the width of its respective deposition region 412 along the direction of motion for mask 1500 (i.e., the x-direction in the present example).

Mask regions 1502 are analogous to mask regions 1302 described above; however, the factor f is now negative (f<0) each mask region 1502 is a rectangular opening having width that is smaller than XR by factor If′, i.e. Xg=(1+f)*XR and the width of barriers 1504 between mask regions 1502 is is larger (1−f)*XR. As a result, each mask region 1502 has a width XR-Xe along the x-direction. Mask regions 1502 are spaced apart along the x-direction by a distance equal to XR+Xe.

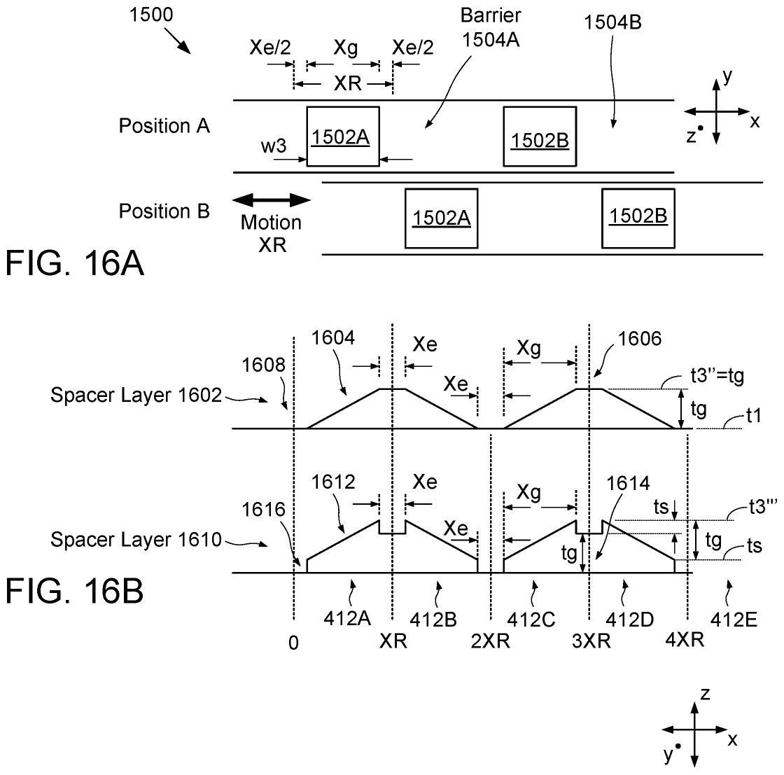

FIG. 16A depicts a schematic drawing of a plan view of a portion of mask 1500 at two points of its motion during sub-operation 1103 of alternative operation 202A.

FIG. 16B depicts schematic drawings of cross-sectional views of two different non-uniform-thickness layers formed during alternative operation 202A using mask 1500, with and without including mask stopping, respectively. Spacer layers 1602 and 1610 are analogous to spacer layer 106 described above.

Layer 1602 includes gradient regions 1604 and boundary regions 1606 and 1608. Dicing is usually performed in the boundary regions.

A continuous back-and-forth motion of mask 1500 during sub-operation 1103 results in boundary regions 1606 receiving deposited material for a time equal to that of the maximum exposure time in the graded region 1604. As a result, these regions have a substantially uniform thickness, t3″, which is equal to the thickness change, tg, across the width of gradient region 1604. However, regions 1608 receive substantially no material flux during the deposition period; therefore, these regions have a thickness, t1, which is approximately equal to zero. It should be noted that, in some cases, a small amount of material will be deposited in the boundary regions due to the finite sizes (Ds) of material sources and limits on the separations between the source, mask, and substrate (i.e., d1 and d2) in practical deposition systems, such as system 400.

As discussed above, after dicing, each resultant die will include a substantially annular region that includes portions of each of boundary regions 1606 and 1608, as well as the boundary region located beneath borders 508 during deposition of graded layer 1602. As a result, the portions of this annular region including boundary regions 1608 and the regions beneath borders 508 have a thickness that is less than that of gradient region 1604.

It should be noted that the maximum thickness t3″ of layer 1602 is thinner than the maximum thickness of layer 1402 (i.e., thickness t3 obtained with f>0 using mask 1300) by an amount approximately equal to t3″=t3*(1−|f|) due to the maximum exposure time being only (1−|f|) of the total exposure time. Thus, to produce a graded layer having a given maximum thickness, t3, using a mask having f<0, requires [1/(1−|f|)] machine time and materials as required for forming layer 1402.

Spacer layer 1610 includes gradient regions 1612 and boundary regions 1614 and 1616 and is formed in the same manner as spacer layer 1602; however, with the inclusion of mask stop periods during sub-operation 1103.

During the stop periods of sub-operation 1103, boundary regions 1614 and 1616 receive virtually no material. As a result, the total material thickness in region 1616, is substantially equal to ts, which is substantially zero, and the total material thickness in region 1614 is substantially equal to tg.

It can be seen, therefore, that using a sliding mask with f<0 and incorporating mask stopping to enables higher wafer-use efficiency. Layer 1610 has maximum thickness, t3″, which is equal to the sum of the stopped-portion thickness ts and the graded-portion maximum thickness tg.

It is useful to compare using layer 1610 with layer 1402, for example, using mask 1500 with an f of −0.01 (linear efficiency is 0.99) and mask stopping with T_{F}=0.6636) instead of mask 1300 with an f=0.667 (linear efficiency is 0.333 and T_{F}=0). The linear efficiency using mask 1500 with stopping is 2.97 times larger than by using mask 1300 with no stopping. However, an additional time Tₛ is required to produce the same layer 1610 due to the mask-stopped deposition having to be made twice since it only deposits in half of the regions during a stop. Thus, it requires about 1.6636 times longer to deposit layer 1610 than for layer 1402, but since the wafer yield (linear efficiency) is about 2.97 greater for layer 1610, the overall efficiency advantage is about (2.97/1.6636)=1.79 times greater for layer 1610 over layer 1402.

Another method for adding a constant-thickness sublayer to a graded layer in accordance with the present disclosure is to employ a clear pathway, without the inclusion of a mask, between the source and the wafer, which will result in substantially uniformly deposition of material onto substrate 102. This operation can be performed before, during, and/or after deposition of the graded portion without departing from the scope of the present disclosure.

Typically, the relative motion of a mask in accordance with the present disclosure relative to the underlying substrate (referred to, for clarity of description, as simply “motion of the mask”) can be expressed in half-periods, where a full period would encompass the complete back-and-forth total relative motion between them. For sliding masks, such as masks 1000 and 1300, a single half-period of motion can produce a desired thickness variation, and it is preferable that each graded layer be produced by an integral number of half-period motions. One or more pairs of fractional stop times may be included at the extreme ends of the motion.

In some embodiments, the motion of a mask is different (e.g. in speed, profile, etc.) during its second half period from its motion during its first half period, thereby producing filters having 2 different configurations on a single wafer. Similarly, the stopping time Tₛ may differ in alternating stopped depositions.

It should be noted that the fractional stop times may take place at any time during the deposition process without departing from the scope of the present disclosure. Exemplary stop times include, without limitation, the beginning of the deposition, the end of the deposition, one or more points during the deposition, and the like.

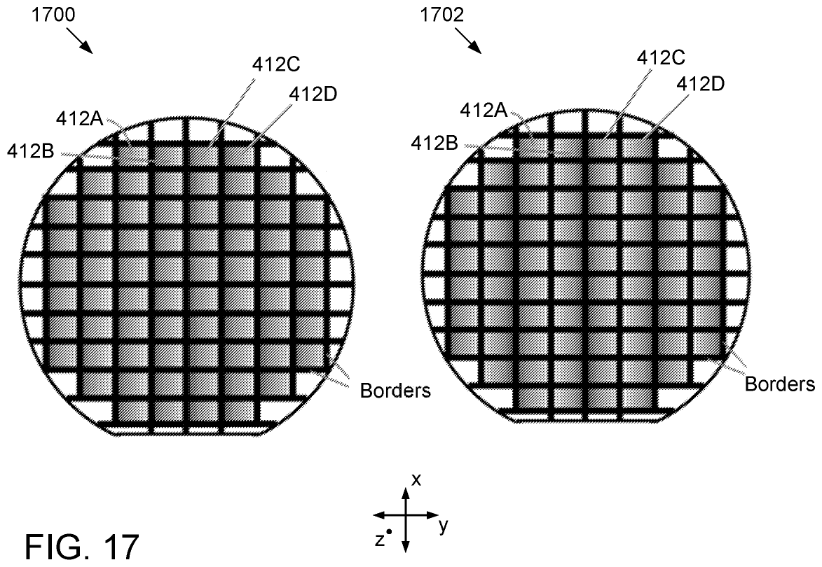

FIG. 17 depicts plan views of two substrates on which a non-uniform-thickness layer has been formed in accordance with the present disclosure.

Substrate 1700 is a substrate on which a non-uniform-thickness layer has been formed using a stencil mask (e.g., mask 404).

Substrate 1702 is a substrate on which a non-uniform-thickness layer has been formed using a sliding mask (e.g., masks 1000, 1300, and 1500).

In the depicted examples, each material pattern on a substrate is depicted with darker shading corresponds to thinner layers, including in border regions, except that all the border regions are shown in black, whether they are representative of the thinnest or thickest portions of the non-uniform-thickness layer.

As noted above, typically, a single material pattern is reproduced at each deposition site over a substrate. In the case of substrate 1700, the material patterns on every deposition site are linear gradients that are substantially identical with their thickness gradients decreasing along the x-direction.

In the case of substrate 1702 the material patterns on every deposition site are also linear gradients; however, the direction of adjacent material patterns have thickness gradients that alternate from increasing and decreasing along the x-direction.

In some embodiments, not all material patterns formed on the deposition sites of a substrate are identical. For example, in some embodiments, different material patterns on a substrate are designed for different optical elements. As a result, any material pattern can have any desired form, such as different thickness-gradients, different thickness ranges, different average thicknesses, and the like. This enables substantially optimized production throughput, product uniformity, and high-quality layers. In order to realize very high-quality layers, in some cases it is desirable to orient substrate 102 such that its surface is substantially perpendicular to source 404 (as opposed to being tilted at a strong angle (e.g. 30-60 degrees) as commonly practiced in the prior art).

In either of the stencil- or sliding-mask embodiments, optical elements may be produced with gradients over widths as small as 1 mm or less, to unlimited widths such as 500 mm or more.

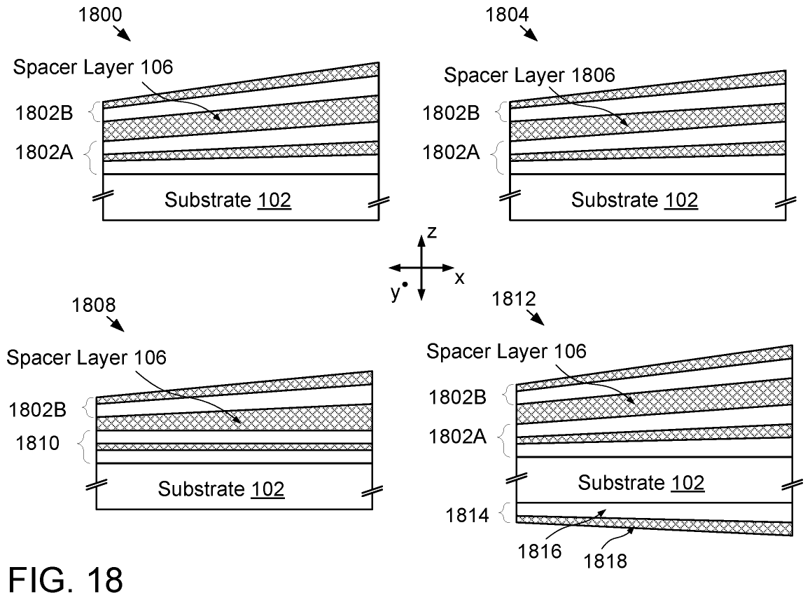

FIG. 18 depicts schematic drawings of cross-sectional views of some alternative optical elements in accordance with the present disclosure. Element 1800 comprises Bragg mirrors 1802A and 1802B, which are separated by spacer layer 106.

Mirrors 1802A and 1802B are analogous to mirror 104A and 104B described above; however, each of the HRI and LRI layers in mirrors 1802A and 1802B has a graded thickness along the x-direction such their thickness increases linearly from one-quarter of the minimum wavelength of interest in light signal 112 (within its respective material) to one-quarter of the maximum wavelength of interest in light signal 112 (within its respective material).

Spacer layer 106 has a gradient along the x-direction similar to that of each of the HRI and LRI layers of 1802A and 1802B.

As a result, element 1800 substantially maximizes filter performance over the wavelength range of interest. In the depicted example, the wavelength range of interest is from approximately 3 microns to approximately 12 microns. In some embodiments, the very large wavelength range of element 1800 gives rise to a need for a separate wavelength-blocking filter located, for example, on the back side of the substrate. In some such embodiments, the wavelength-blocking filter includes a thickness gradient similar to those described herein.

Element 1804 comprises Bragg mirrors 1802A and 1802B, which are separated by spacer layer 1806.

Spacer layer 1806 is analogous to spacer layer 106 described above; however, spacer layer 1806 has a substantially uniform thickness along the x-direction.

Element 1808 comprises Bragg mirrors 1810 and 1802B, which are separated by spacer layer 106.

Mirror 1810 comprises HRI and LRI layers having a thickness equal to ¼ of the center wavelength of light signal 112.

In some embodiments, one or more layers of an optical element has a thickness equal to ¼ of a different wavelength within the spectral range of light signal 112.

Element 1812 is analogous to element 1800; however, element 1808 includes structure 1814 on the opposite side of substrate 102. In the depicted example, structure 1814 is an anti-reflection filter comprising non-uniform-thickness layers 1816 and 1818, which are analogous to HRI and LRI layers described above.

It should be noted that an anti-reflection filter is merely one of myriad functions for which structure 1814 can be configured. For example, in some embodiments, structure 1814 is configured to transmit a wavelength band that is wider than the transmission band of optical element disposed on the opposite side of substrate 102 such that structure 1814 blocks unwanted wavelengths passed by that optical element (i.e., a wide-bandpass filter). In some embodiments, structure 1814 includes one or more edge filters, which may be short-wave pass or long-wave pass. It will be apparent to one skilled in the art, after reading this Specification, how to specify, make, and use any of a wide range of structures suitable for use as structure 1814.

It should be noted that a Bragg mirror included in any optical element in accordance with the present disclosure can be configured for operation at any wavelength. For example, in some embodiments including a pair of mirrors separated by a spacer layer, the mirrors can be centered at different wavelengths, thereby increasing the overall wavelength blocking range.

It is to be understood that the disclosure teaches just some examples of embodiments in accordance with the present disclosure and that many variations of the invention can easily be devised by those skilled in the art after reading this disclosure and that the scope of the present invention is to be determined by the following claims.

What is claimed is:

1. A method for forming a plurality of optical elements on a substrate, the method including forming a first layer on the substrate such that the first layer includes a plurality of material patterns on a plurality of deposition sites located on the substrate, wherein a first material pattern of the plurality of material patterns has a thickness that includes a desired non-uniformity along a first direction, and wherein the first layer is formed by operations comprising:
providing a mask having a plurality of mask regions;
locating the mask between a material source and the substrate; and
directing a material flux from the material source through the plurality of mask regions to form the plurality of material patterns.

2. The method of claim 1 wherein the mask is provided such that it includes a plurality of mask regions, each mask region comprising a series of openings distributed along the first direction and a series of barriers distributed along the first direction, wherein each barrier is located between a different pair of adjacent openings of the series thereof, and wherein each opening of the plurality of openings has an opening width along the first direction that is based on the position of that opening within the series of openings.

3. The method of claim 2 wherein each barrier has a barrier width that is based on its position within the series of barriers.

4. The method of claim 2 wherein the opening widths of the series of openings change monotonically along the first direction and the barrier widths of the series of barriers change monotonically along the first direction.

5. The method of claim 2 further comprising imparting a relative motion between the mask and the substrate along the first direction.

6. The method of claim 6 wherein the relative motion is a dithering of at least one of the mask and the substrate.

7. The method of claim 1 wherein the mask is provided such that it includes a plurality of mask regions, each mask region comprising a single opening having an opening width along the first direction, and wherein the method further comprising imparting a relative motion between the mask and the substrate along the first direction while the material flux passes through the plurality of mask regions.

8. The method of claim 7 wherein at least one deposition site of the plurality thereof has a first width along the first direction, and wherein the relative motion is a back-and-forth motion over a distance equal to the first width.

9. The method of claim 8 wherein the first mask region has a second width along the first direction that is larger than the first width, and wherein the relative motion includes a stopping time during which the mask and substrate are held fixed at each end of their relative travel.

10. The method of claim 8 wherein the first mask region has a second width along the first direction that is smaller than the first width, and wherein the relative motion includes a stopping time during which the mask and substrate are held fixed at each end of their relative travel.

11. The method of claim 1 wherein the first material pattern is formed on a first mirror disposed on the substrate, and wherein the method further includes forming a second mirror disposed on the first material pattern.

12. The method of claim 1 further comprising separating the substrate into a plurality of individual chips after formation of the first layer, each chip including an optical element.

13. An apparatus comprising:
a plurality of optical elements disposed on a substrate, each optical element including a different portion of a first layer that includes a plurality of material patterns, wherein each material pattern has a thickness that has a desired non-uniformity along a first direction; and
a plurality of boundary regions, each boundary region being located between a pair of adjacent material patterns along the first direction.

14. The method of claim 13 wherein the desired non-uniformity is a thickness gradient.

15. The method of claim 13 wherein each optical element of the plurality thereof further includes:
a first Bragg mirror located between the substrate and the first layer; and
a second Bragg mirror disposed on the first layer such that the first layer is between the first and second Bragg mirrors.
